(19) United States
(12) Patent Application Publication
(10) Pub. No.: US 2003/0088375 A1
(43) Pub. Date: May 8, 2003

(54) Electronic battery tester with relative test output

(76) Inventors: Kevin I. Bertness, Batavia, IL (US); J. David Vonderhaar, Bolingbrook, IL (US)

Correspondence Address: WESTMAN, CHAMPLIN & KELLY, INTERNATIONAL CENTRE - SUITE 1600, 900 SECOND AVENUE SOUTH, MINNEAPOLIS, MN, 55402-3319, US

(21) Appl. No.: 10/263,473

(22) Filed: Oct. 2, 2002

Related U.S. Application Data
(60) Provisional application No. 60/330,441, filed on Oct. 17, 2001.

(51) Int. Cl. G06F 19/00; G01R 31/36

(52) U.S. Cl. 702/63

(57) ABSTRACT

An electronic battery tester for testing a storage battery determines a condition of the battery. The condition is a relative condition and is a function of a dynamic parameter of the battery and an empirical input variable.

### BACKGROUND OF THE INVENTION

The present application is based on and claims the benefit of U.S. provisional patent application Serial No. 60/330,441, filed Oct. 17, 2001, the content of which is hereby incorporated by reference in its entirety.

The present invention relates to measuring the condition of storage batteries. More specifically, the present invention relates to electronic battery testers which measure a dynamic parameter of batteries.

Electronic battery testers are used to test storage batteries. Various examples of such testers are described in U.S. Pat. No. 3,873,911, issued Mar. 25, 1975, to Champlin, entitled ELECTRONIC BATTERY TESTING DEVICE; U.S. Pat. No. 3,909,708, issued Sep. 30, 1975, to Champlin, entitled ELECTRONIC BATTERY TESTING DEVICE; U.S. Pat. No. 4,816,768, issued Mar. 28, 1989, to Champlin, entitled ELECTRONIC BATTERY TESTING DEVICE; U.S. Pat. No. 4,825,170, issued Apr. 25, 1989, to Champlin, entitled ELECTRONIC BATTERY TESTING DEVICE WITH AUTOMATIC VOLTAGE SCALING; U.S. Pat. No. 4,881,038, issued Nov. 14, 1989, to Champlin, entitled ELECTRONIC BATTERY TESTING DEVICE WITH AUTOMATIC VOLTAGE SCALING TO DETERMINE DYNAMIC CONDUCTANCE; U.S. Pat. No. 4,912,416, issued Mar. 27, 1990, to Champlin, entitled ELECTRONIC BATTERY TESTING DEVICE WITH STATE-OF-CHARGE COMPENSATION; U.S. Pat. No. 5,140,269, issued Aug. 18, 1992, to Champlin, entitled ELECTRONIC TESTER FOR ASSESSING BATTERY/CELL CAPACITY; U.S. Pat. No. 5,343,380, issued Aug. 30, 1994, entitled METHOD AND APPARATUS FOR SUPPRESSING TIME VARYING SIGNALS IN BATTERIES UNDERGOING CHARGING OR DISCHARGING; U.S. Pat. No. 5,572,136, issued Nov. 5, 1996, entitled ELECTRONIC BATTERY TESTER WITH AUTOMATIC COMPENSATION FOR LOW STATE-OF-CHARGE; U.S. Pat. No. 5,574,355, issued Nov. 12, 1996, entitled METHOD AND APPARATUS FOR DETECTION AND CONTROL OF THERMAL RUNAWAY IN A BATTERY UNDER CHARGE; U.S. Pat. No. 5,585,416, issued Dec. 10, 1996, entitled APPARATUS AND METHOD FOR STEP-CHARGING BATTERIES TO OPTIMIZE CHARGE ACCEPTANCE; U.S. Pat. No. 5,585,728, issued Dec. 17, 1996, entitled ELECTRONIC BATTERY TESTER WITH AUTOMATIC COMPENSATION FOR LOW STATE-OF-CHARGE; U.S. Pat. No. 5,589,757, issued Dec. 31, 1996, entitled APPARATUS AND METHOD FOR STEP-CHARGING BATTERIES TO OPTIMIZE CHARGE ACCEPTANCE; U.S. Pat. No. 5,592,093, issued Jan. 7, 1997, entitled ELECTRONIC BATTERY TESTING DEVICE LOOSE TERMINAL CONNECTION DETECTION VIA A COMPARISON CIRCUIT; U.S. Pat. No. 5,598,098, issued Jan. 28, 1997, entitled ELECTRONIC BATTERY TESTER WITH VERY HIGH NOISE IMMUNITY; U.S. Pat. No. 5,656,920, issued Aug. 12, 1997, entitled METHOD FOR OPTIMIZING THE CHARGING LEAD-ACID BATTERIES AND AN INTERACTIVE CHARGER; U.S. Pat. No. 5,757,192, issued May 26, 1998, entitled METHOD AND APPARATUS FOR DETECTING A BAD CELL IN A STORAGE BATTERY; U.S. Pat. No. 5,821,756, issued Oct. 13, 1998, entitled ELECTRONIC BATTERY TESTER WITH TAILORED COMPENSATION FOR LOW STATE-OF-CHARGE; U.S. Pat. No. 5,831,435, issued Nov. 3, 1998, entitled BATTERY TESTER FOR JIS STANDARD; U.S. Pat. No. 5,914,605, issued Jun. 22, 1999, entitled ELECTRONIC BATTERY TESTER; U.S. Pat. No. 5,945,829, issued Aug. 31, 1999, entitled MIDPOINT BATTERY MONITORING; U.S. Pat. No. 6,002,238, issued Dec. 14, 1999, entitled METHOD AND APPARATUS FOR MEASURING COMPLEX IMPEDANCE OF CELLS AND BATTERIES; U.S. Pat. No. 6,037,751, issued Mar. 14, 2000, entitled APPARATUS FOR CHARGING BATTERIES; U.S. Pat. No. 6,037,777, issued Mar. 14, 2000, entitled METHOD AND APPARATUS FOR DETERMINING BATTERY PROPERTIES FROM COMPLEX IMPEDANCE/ADMITTANCE; U.S. Pat. No. 6,051,976, issued Apr. 18, 2000, entitled METHOD AND APPARATUS FOR AUDITING A BATTERY TEST; U.S. Pat. No. 6,081,098, issued Jun. 27, 2000, entitled METHOD AND APPARATUS FOR CHARGING A BATTERY; U.S. Pat. No. 6,091,245, issued Jul. 18, 2000, entitled METHOD AND APPARATUS FOR AUDITING A BATTERY TEST; U.S. Pat. No. 6,104,167, issued Aug. 15, 2000, entitled METHOD AND APPARATUS FOR CHARGING A BATTERY; U.S. Pat. No. 6,137,269, issued Oct. 24, 2000, entitled METHOD AND APPARATUS FOR ELECTRONICALLY EVALUATING THE INTERNAL TEMPERATURE OF AN ELECTROCHEMICAL CELL OR BATTERY; U.S. Pat. No. 6,163,156, issued Dec. 19, 2000, entitled ELECTRICAL CONNECTION FOR ELECTRONIC BATTERY TESTER; U.S. Pat. No. 6,172,483, issued Jan. 9, 2001, entitled METHOD AND APPARATUS FOR MEASURING COMPLEX IMPEDANCE OF CELL AND BATTERIES; U.S. Pat. No. 6,172,505, issued Jan. 9, 2001, entitled ELECTRONIC BATTERY TESTER; U.S. Pat. No. 6,222,369, issued Apr. 24, 2001, entitled METHOD AND APPARATUS FOR DETERMINING BATTERY PROPERTIES FROM COMPLEX IMPEDANCE/ADMITTANCE; U.S. Pat. No. 6,225,808, issued May 1, 2001, entitled TEST COUNTER FOR ELECTRONIC BATTERY TESTER; U.S. Pat. No. 6,249,124, issued Jun. 19, 2001, entitled ELECTRONIC BATTERY TESTER WITH INTERNAL BATTERY; U.S. Pat. No. 6,259,254, issued Jul. 10, 2001, entitled APPARATUS AND METHOD FOR CARRYING OUT DIAGNOSTIC TESTS ON BATTERIES AND FOR RAPIDLY CHARGING BATTERIES; U.S. Pat. No. 6,262,563, issued Jul. 17, 2001, entitled METHOD AND APPARATUS FOR MEASURING COMPLEX ADMITTANCE OF CELLS AND BATTERIES; U.S. Pat. No. 6,294,896, issued Sep. 25, 2001; entitled METHOD AND APPARATUS FOR MEASURING COMPLEX SELF-IMMITANCE OF A GENERAL ELECTRICAL ELEMENT; U.S. Pat. No. 6,294,897, issued Sep. 25, 2001, entitled METHOD AND APPARATUS FOR ELECTRONICALLY EVALUATING THE INTERNAL TEMPERATURE OF AN ELECTROCHEMICAL CELL OR BATTERY; U.S. Pat. No. 6,304,087, issued Oct. 16, 2001, entitled APPARATUS FOR CALIBRATING ELECTRONIC BATTERY TESTER; U.S. Pat. No. 6,310,481, issued Oct. 30, 2001, entitled ELECTRONIC BATTERY TESTER; U.S. Pat. No. 6,313,607, issued Nov. 6, 2001, entitled METHOD AND APPARATUS FOR EVALUATING STORED CHARGE IN AN ELECTROCHEMICAL CELL OR BATTERY; U.S. Pat. No. 6,313,608, issued Nov. 6, 2001, entitled METHOD AND APPARATUS FOR CHARGING A BATTERY; U.S. Pat. No. 6,316,914, issued Nov. 13, 2001, entitled TESTING PARALLEL STRINGS OF STORAGE BATTERIES; U.S. Pat. No. 6,323,650, issued Nov. 27, 2001, entitled ELECTRONIC BATTERY TESTER; U.S. Pat. No. 6,329,793, issued Dec. 11, 2001, entitled METHOD AND APPARATUS FOR CHARGING A BATTERY; U.S. Pat. No. 6,331,762, issued Dec. 18, 2001, entitled ENERGY MANAGEMENT SYSTEM FOR AUTOMOTIVE VEHICLE; U.S. Pat. No. 6,332,113, issued Dec. 18, 2001, entitled ELECTRONIC BATTERY TESTER; U.S. Pat. No. 6,351,102, issued Feb. 26, 2002, entitled AUTOMOTIVE BATTERY CHARGING SYSTEM TESTER; U.S. Pat. No. 6,359,441, issued Mar. 19, 2002, entitled ELECTRONIC BATTERY TESTER; U.S. Pat. No. 6,363,303, issued Mar. 26, 2002, entitled ALTERNATOR DIAGNOSTIC SYSTEM, U.S. Pat. No. 6,392,414, issued May 21, 2002, entitled ELECTRONIC BATTERY TESTER; U.S. Pat. No. 6,417,669, issued Jul. 9, 2002, entitled SUPPRESSING INTERFERENCE IN AC MEASUREMENTS OF CELLS, BATTERIES AND OTHER ELECTRICAL ELEMENTS; U.S. Pat. No. 6,424,158, issued Jul. 23, 2002, entitled APPARATUS AND METHOD FOR CARRYING OUT DIAGNOSTIC TESTS ON BATTERIES AND FOR RAPIDLY CHARGING BATTERIES; U.S. Pat. No. 6,441,585, issued Aug. 17, 2002, entitled APPARATUS AND METHOD FOR TESTING RECHARGEABLE ENERGY STORAGE BATTERIES; U.S. Pat. No. 6,445,158, issued Sep. 3, 2002, entitled VEHICLE ELECTRICAL SYSTEM TESTER WITH ENCODED OUTPUT; U.S. Pat. No. 6,456,045, issued Sep. 24, 2002, entitled INTEGRATED CONDUCTANCE AND LOAD TEST BASED ELECTRONIC BATTERY TESTER; U.S. Ser. No. 09/703,270, filed Oct. 31, 2000, entitled ELECTRONIC BATTERY TESTER; U.S. Ser. No. 09/780,146,filed Feb. 9, 2001, entitled STORAGE BATTERY WITH INTEGRAL BATTERY TESTER; U.S. Ser. No. 09/816,768, filed Mar. 23, 2001, entitled MODULAR BATTERY TESTER; U.S. Ser. No. 09/756,638, filed Jan. 8, 2001, entitled METHOD AND APPARATUS FOR DETERMINING BATTERY PROPERTIES FROM COMPLEX IMPEDANCE/ADMITTANCE; U.S. Ser. No. 09/862,783, filed May 21, 2001, entitled METHOD AND APPARATUS FOR TESTING CELLS AND BATTERIES EMBEDDED IN SERIES/PARALLEL SYSTEMS; U.S. Ser. No. 09/483,623, filed Jan. 13, 2000, entitled ALTERNATOR TESTER; U.S. Ser. No. 09/960,117, filed Sep. 20, 2001, entitled IN-VEHICLE BATTERY MONITOR; U.S. Ser. No. 09/908,389, filed Jul. 18, 2001, entitled BATTERY CLAMP WITH INTEGRATED CIRCUIT SENSOR; U.S. Ser. No. 09/908,278, filed Jul. 18, 2001, entitled BATTERY CLAMP WITH EMBEDDED ENVIRONMENT SENSOR; U.S. Ser. No. 09/880,473, filed Jun. 13, 2001; entitled BATTERY TEST MODULE; U.S. Ser. No. 09/940,684, filed Aug. 27, 2001, entitled METHOD AND APPARATUS FOR EVALUATING STORED CHARGE IN AN ELECTROCHEMICAL CELL OR BATTERY; U.S. Ser. No. 09/977,049, filed Oct. 12, 2001, entitled PROGRAMMABLE CURRENT EXCITER FOR MEASURING AC IMMITTANCE OF CELLS AND BATTERIES; U.S. Serial No. 60/330,441, filed Oct. 17, 2001, entitled ELECTRONIC BATTERY TESTER WITH RELATIVE TEST OUTPUT; U.S. Serial No. 60/348,479, filed Oct. 29, 2001, entitled CONCEPT FOR TESTING HIGH POWER VRLA BATTERIES; U.S. Ser. No. 10/046,659, filed Oct. 29, 2001, entitled ENERGY MANAGEMENT SYSTEM FOR AUTOMOTIVE VEHICLE; U.S. Ser. No. 09/993,468, filed Nov. 14, 2001, entitled KELVIN CONNECTOR FOR A BATTERY POST; U.S. Ser. No. 09/992,350, filed Nov. 26, 2001, entitled ELECTRONIC BATTERY TESTER, U.S. Serial No. 60/341,902, filed Dec. 19, 2001, entitled BATTERY TESTER MODULE; U.S. Ser. No. 10/042,451, filed Jan. 8, 2002, entitled BATTERY CHARGE CONTROL DEVICE, U.S. Ser. No. 10/073,378, filed Feb. 8, 2002, entitled METHOD AND APPARATUS USING A CIRCUIT MODEL TO EVALUATE CELL/BATTERY PARAMETERS; U.S. Ser. No. 10/093,853, filed Mar. 7, 2002, entitled ELECTRONIC BATTERY TESTER WITH NETWORK COMMUNICATION; U.S. Serial No. 60/364,656, filed Mar. 14, 2002, entitled ELECTRONIC BATTERY TESTER WITH LOW TEMPERATURE RATING DETERMINATION; U.S. Ser. No. 10/098,741, filed Mar. 14, 2002, entitled METHOD AND APPARATUS FOR AUDITING A BATTERY TEST; U.S. Ser. No. 10/101,543, filed Mar. 19, 2002, entitled ELECTRONIC BATTERY TESTER; U.S. Ser. No. 10/112,114, filed Mar. 28, 2002; U.S. Ser. No. 10/109,734, filed Mar. 28, 2002; U.S. Ser. No. 10/112,105, filed Mar. 28, 2002, entitled CHARGE CONTROL SYSTEM FOR A VEHICLE BATTERY; U.S. Ser. No. 10/112,998, filed Mar. 29, 2002, entitled BATTERY TESTER WITH BATTERY REPLACEMENT OUTPUT; U.S. Ser. No. 10/119,297, filed Apr. 9, 2002, entitled METHOD AND APPARATUS FOR TESTING CELLS AND BATTERIES EMBEDDED IN SERIES/PARALLEL SYSTEMS; U.S. Ser. No. 10/128,790, filed Apr. 22, 2002, entitled METHOD OF DISTRIBUTING JUMP-START BOOSTER PACKS; U.S. Serial No. 60/379,281, filed May 8, 2002, entitled METHOD FOR DETERMINING BATTERY STATE OF CHARGE; U.S. Ser. No. 10/143,307, filed May 10, 2002, entitled ELECTRONIC BATTERY TESTER; U.S. Serial No. 60/387,046, filed Jun. 7, 2002, entitled METHOD AND APPARATUS FOR INCREASING THE LIFE OF A STORAGE BATTERY; U.S. Ser. No. 10/177,635, filed Jun. 21, 2002, entitled BATTERY CHARGER WITH BOOSTER PACK; U.S. Ser. No. 10/207,495, filed Jul. 29, 2002, entitled KELVIN CLAMP FOR ELECTRICALLY COUPLING TO A BATTERY CONTACT; U.S. Ser. No. 10/200,041, filed Jul. 19, 2002, entitled AUTOMOTIVE VEHICLE ELECTRICAL SYSTEM DIAGNOSTIC DEVICE; U.S. Ser. No. 10/217,913, filed Aug. 13, 2002, entitled, BATTERY TEST MODULE; U.S. Serial No. 60/408,542, filed Sep. 5, 2002, entitled BATTERY TEST OUTPUTS ADJUSTED BASED UPON TEMPERATURE; U.S. Ser, No. 10/______, (C382.12-0124), filed Sep. 18, 2002, entitled BATTERY TESTER UPGRADE USING SOFTWARE KEY; U.S. Serial No. 60/______, (C382.12-0137), filed on even date herewith, entitled QUERY BASED ELECTRONIC BATTERY TESTER, which are incorporated herein in their entirety.

It is known that the condition of a battery can be provided by comparing a rating of the battery with a measured value. However, other techniques for providing a relative battery test could provide additional information regarding battery condition.

### SUMMARY OF THE INVENTION

An electronic battery tester for testing a storage battery provides a relative test output indicative of a condition of the battery as a function of a measured dynamic parameter of the battery and at least one empirical input variable. The tester includes first and second Kelvin connections configured to electrically couple to terminals of the battery. Dynamic parameter measurement circuitry provides a dynamic parameter output related to a dynamic parameter of the battery. Calculation circuitry provides the relative test output as a function of the dynamic parameter and the empirical input variable.

### BRIEF DESCRIPTION OF THE DRAWINGS

FIG. 1 is a simplified block diagram of an electronic battery tester in accordance with the present invention.

FIG. 2 is a more detailed block diagram of the battery tester of FIG. 1.

FIG. 3 is a simplified flow chart showing steps in accordance with the present invention.

### DETAILED DESCRIPTION OF THE PREFERRED EMBODIMENTS

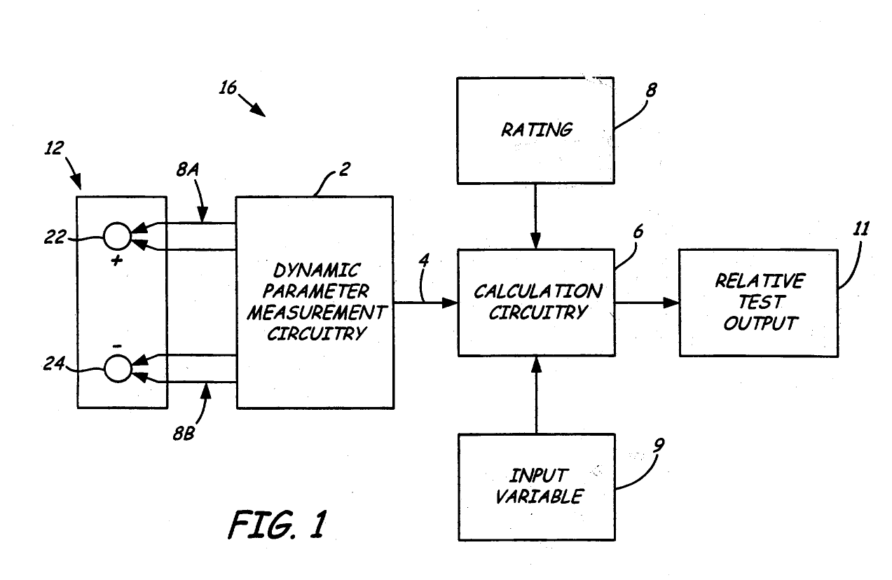

FIG. 1 is a simplified block diagram of electronic battery tester 16 in accordance with the present invention. Apparatus 16 is shown coupled to battery 12 which includes a positive battery terminal 22 and a negative battery terminal 24. Battery 12 is a storage battery having a plurality of individual cells and a voltage such as 12.6 volts, 48 volts, etc.

FIG. 1 operates in accordance with the present invention and includes dynamic parameter measurement circuitry 2 which is configured to measure a dynamic parameter of battery 12 through first and second Kelvin connections 8A and 8B. Dynamic parameter measurement circuitry 2 measures a dynamic parameter, that is a parameter which is a function of a signal with a time varying component, of battery 12 and provides a dynamic parameter output 4 to calculation circuitry 6. Example dynamic parameters include dynamic conductance resistance, reactance, susceptance, and their combinations. Calculation circuitry 6 receives the dynamic parameter output 4 and an optional rating 8 which relates to a rating of battery 12 and an empirical input variable 9. Based upon the optional rating, the empirical input variable and the measured dynamic parameter output 4, calculation circuitry 6 responsively provides a relative test output 11 of battery 12.

In various aspects of the invention, the relative test output can be various relative indications of a battery's condition. For example, in one embodiment, the relative test output is indicative of a time required to charge the battery. In such an embodiment, the possible input variables include the size of the battery and the available charge current. Another example relative test output is the condition of the battery relative to a particular geographic area. In such an embodiment the input variable can comprise geographical information. For example, a battery suitable for use in warm regions, such as the southern United States may not be suitable for use in colder regions such as the northern United States. Further, such geographical information can be used in estimating aging of a battery. A battery in certain climates may age faster than a battery in other climates or areas. Further, a “weak” battery may be suitable for use in some geographical areas but not others. Another example relative test output is a run time output indicative of the time a battery can supply a required power level to a load. In such an embodiment the input variable can be the load size or required power.

Another example relative test output is an end of life output indicative of an estimated remaining life of the battery. In such an embodiment the input variable can comprise certain minimum requirements for a particular battery below which the battery's life will be considered to have ended.

Another relative test output comprises a vehicle size output which is indicative of the size of a vehicle, or a size of an engine of a vehicle, for which the battery can be used. For example, some vehicles or engines may require larger batteries. In such an embodiment, the input variable can comprise information related to vehicle size, vehicle type or engine size.

Another example relative test output comprises a battery condition output which is compensated based upon the age of the battery. In one embodiment, the battery test is tested using more difficult criteria if the battery is new to ensure high deliverable quality. In another example, an older battery may also be tested more severely as an older battery is more likely to be defective. In such an embodiment the input variable can be related to the battery age.

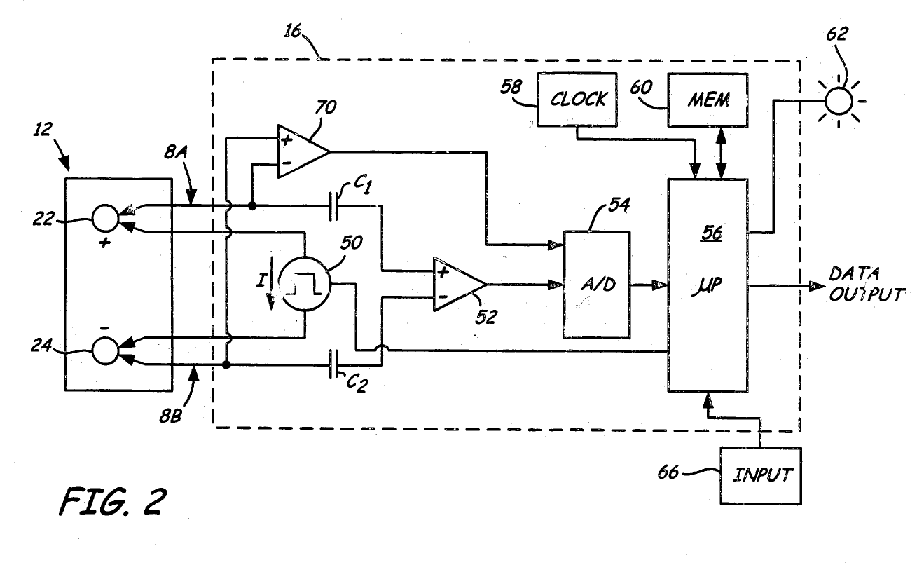

FIG. 2 is a more detailed block diagram of circuitry 16 which operates in accordance with one embodiment of the present invention and determines a dynamic parameter such as the conductance (G_{BAT}) of battery 12 and the voltage potential (V_{BAT}) between terminals 22 and 24 of battery 12. Circuitry 16 includes a forcing function such as current source 50, differential amplifier 52, analog-to-digital converter 54 and microprocessor 56. In this embodiment, dynamic parameter measurement circuitry 2 shown in FIG. 1 generally comprises source 50, amplifier 52, analog to digital converter 54, amplifier 70 and microprocessor 56. Calculation circuitry 6 generally comprises microprocessor 56. The general blocks shown in FIG. 1 can be implemented as desired and are not limited to the configurations shown in FIG. 2. Amplifier 52 is capacitively coupled to battery 12 through capacitors C₁ and C₂. Amplifier 52 has an output connected to an input of analog-to-digital converter 54. Microprocessor 56 is connected to system clock 58, memory 60, pass/fail indicator 62 and analog-to-digital converter 54. Microprocessor 56 is also capable of receiving an input from input device 66. The input can be the empirical input variable, a rating of the battery, or other data as desired.

In operation, current source 50 is controlled by microprocessor 56 and provides a current in the direction shown by the arrow in FIG. 2. This can be any type of time varying signal. Source 50 can be an active source or a passive source such as a resistance. Differential amplifier 52 is connected to terminals 22 and 24 of battery 12 through capacitors C₁ and C₂, respectively, and provides an output related to the voltage potential difference between terminals 22 and 24. In a preferred embodiment, amplifier 52 has a high input impedance. Circuitry 16 includes differential amplifier 70 having inverting and noninverting inputs connected to terminals 24 and 22, respectively. Amplifier 70 is connected to measure the open circuit potential voltage (V_{BAT}) of battery 12 between terminals 22 and 24. The output of amplifier 70 is provided to analog-to-digital converter 54 such that the voltage across terminals 22 and 24 can be measured by microprocessor 56.

Circuitry 16 is connected to battery 12 through a four-point connection technique known as a Kelvin connection. This Kelvin connection allows current I to be injected into battery 12 through a first pair of terminals while the voltage V across the terminals 22 and 24 is measured by a second pair of connections. Because very little current flows through amplifier 52, the voltage drop across the inputs to amplifier 52 is substantially identical to the voltage drop across terminals 22 and 24 of battery 12. The output of differential amplifier 52 is converted to a digital format and is provided to microprocessor 56. Microprocessor 56 operates at a frequency determined by system clock 58 and in accordance with programming instructions stored in memory 60.

Microprocessor 56 determines the conductance of battery 12 by applying a current pulse I using current source 50. This can be, for example, by selectively applying a load such as a resistance. The microprocessor determines the change in battery voltage due to the current pulse I using amplifier 52 and analog-to-digital converter 54. The value of current I generated by current source 50 is known and is stored in memory 60. In one embodiment, current I is obtained by applying a load to battery 12. Microprocessor 56 calculates the conductance of battery 12 using the following equation:

$$\text{Conductance} = {G}_{BAT} = \frac{Δ I}{Δ V} \qquad \text{Equation 1}$$

where ΔI is the change in current flowing through battery 12 due to current source 50 and AV is the change in battery voltage due to applied current ΔI.

Microprocessor 56 operates in accordance with the present invention and determines the relative test output discussed herein. The relative test output can be provided on the data output. The data output can be a visual display or other device for providing information to an operator and/or can be an output provided to other circuitry.

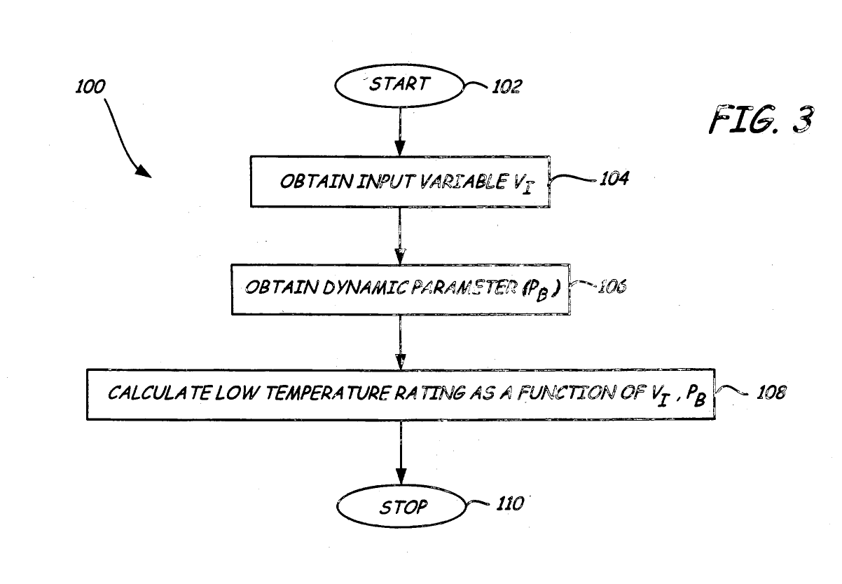

FIG. 3 is a flow chart 100 showing operation of microprocessor 56 based upon programming instructions stored in memory 60. Block diagram 100 begins at start block 102. At block 104, an empirical input variable V_{I} is obtained. This can be, for example, retrieved from memory 60 or received from input 66. At block 106, the dynamic parameter P_{B} is determined. At block 108, the relative test output of the battery is calculated as a function of V_{I} and P_{B}. Block diagram 100 terminates at stop block 110.

Some prior art battery testers have compared a battery measurement to a fixed value, such as a rating of the battery in order to provide a relative output. For example, by comparing a measured value of the battery with the rating of the battery, an output can be provided which is a percentage based upon a ratio of the measured value to the rated value. However, the present invention recognizes that in some instances it may be desirable to provide an operator with some other type of relative output. With the present invention, a relative test output is provided which is a function of a dynamic parameter measurement of the battery and at least one empirical input variable.

As used herein, a dynamic parameter of the battery is a parameter which has been measured using an applied signal (either passively or actively) with a time varying component. Example dynamic parameters include dynamic resistance, conductance, reactance, susceptance and there combinations both real, imaginary and combinations.

An empirical input variable as used herein refers to variables which are observed, measured or otherwise determined during use of battery and are not static variables such as a rating of the battery which is determined during manufacture of the battery. Example empirical input variables include other test results such as load test results, bounce back load test results, voltage measurements, state of charge measurements from specific gravity, voltage or other measurement techniques; visual observations such as terminal corrosion, cracked case or others conditions; charge acceptance from an alternator; charge acceptance from a source of the battery tester; operator or customer behavior information such as how the vehicle is used; vehicle age or condition; change in conductance (or other dynamic parameter) or change in charge acceptance during charge or discharge; data retrieved from a previous test of the battery; battery weight; geographic information; time required to charge the battery; the time or period over which the battery can power a particular load; the vehicle size or engine size that the battery can operate; the number of engine starts performed by the battery per day; or other similar observations or measurements.

Based upon the measured dynamic parameter and the empirical input variable, a relative test output is provided. Examples of a relative test output include an end of life prediction for the battery which can be in the form of months, seasons or other forms; a predicted number of engine starts of the vehicle which the battery can perform; a predicted number of charge and discharge cycles which the battery is capable of experiencing, a prediction of time to reach an end voltage based upon current draw and temperature; a predicted time to charge the battery based upon charge current and temperature; a prediction of the largest current at which a load test applied to the battery can be passed; a prediction of the reserve capacity of the battery; a prediction of the number of amp-hours remaining in the battery, or others.

The relative test output can be shown on a display, used to provide pass/fail information or passed along the other circuitry.

The present invention may be implemented using any appropriate technique. For simplicity, a single technique has been illustrate herein. However, other techniques may be used including implementation in all analog circuitry. Additionally, by using appropriate techniques, any dynamic parameter can be measured. With the present invention, a desired output level of the battery is obtained, for example through an input.

Although the present invention has been described with reference to preferred embodiments, workers skilled in the art will recognize that changes may be made in form and detail without departing from the spirit and scope of the invention. The specific relationship between the relative test output and the empirical input variable can be determined experimentally or by developing models and relationships which characterize the battery as desired.

What is claimed is:

1. An electronic battery tester for testing a storage battery, comprising:
Kelvin connections configured to couple to terminals of the battery;
measurement circuitry coupled to the Kelvin connections configured to measure a dynamic parameter of the battery and a voltage across terminals of the battery;
an empirical variable input configured to receive an empirical input variable;
computation circuitry configured to provide a relative battery test output as a function of the dynamic parameter and the empirical input variable, the relative test output indicative of a condition of the battery.

2. The apparatus of claim 1 wherein the measurement circuitry is further configured to measure a voltage across terminals of the battery and the relative test output is further a function of a voltage and is indicative of a time to charge the battery.

3. The apparatus of claim 1 wherein the dynamic parameter is measured using a time varying signal.

4. The apparatus of claim 1 wherein the empirical input variable comprises a result of a load test.

5. The apparatus of claim 1 wherein the empirical input variable comprises a result of a bounce back load test.

6. The apparatus of claim 1 wherein the empirical input variable comprises voltage measurements.

7. The apparatus of claim 1 wherein the empirical input variable comprises state of charge measurements.

8. The apparatus of claim 1 wherein the empirical input variable comprises a visual observation.

9. The apparatus of claim 8 wherein the visual observation is related to corrosion of terminals of the battery.

10. The apparatus of claim 8 wherein the visual observation is related to a cracked battery case.

11. The apparatus of claim 1 wherein the empirical input variable is related to acceptance of charge by the battery from an alternator.

12. The apparatus of claim 1 wherein the battery tester includes a charging source and the empirical input variable is indicative of charge acceptance by the battery from the source.

13. The apparatus of claim 1 wherein the empirical input variable is related to operator behavior.

14. The apparatus of claim 1 wherein the empirical input variable is indicative of vehicle age.

15. The apparatus of claim 1 wherein the empirical input variable is indicative of vehicle condition.

16. The apparatus of claim 1 wherein the empirical input variable is indicative of a change in a dynamic parameter of the battery.

17. The apparatus of claim 1 wherein the empirical input variable is indicative of charge acceptance of the battery during charging.

18. The apparatus of claim 1 wherein the empirical input variable is indicative of a previous test of the battery.

19. The apparatus of claim 1 wherein the empirical input variable is indicative of battery weight.

20. The apparatus of claim 1 wherein the empirical input variable is indicative of geographic information.

21. The apparatus of claim 1 wherein the empirical input variable is related to time required to charge the battery.

22. The apparatus of claim 1 wherein the empirical input variable is related to a time period during which the battery can power a particular load.

23. The apparatus of claim 1 wherein the empirical input variable is indicative of a vehicle size or engine size that the battery can operate.

24. The apparatus of claim 1 wherein the empirical input variable is related to the number of engine starts performed by the battery per day.

25. The apparatus of claim 1 wherein the relative test output is indicative of a predicted end of life of the battery.

26. The apparatus of claim 1 wherein the relative test output is indicative of a predicted number of engine starts of the vehicle which the battery can perform.

27. The apparatus of claim 1 wherein the relative test output is indicative of a predicted number of charge and discharge cycles which the battery is capable of experiencing.

28. The apparatus of claim 1 wherein the relative test output comprises a prediction of a time to reach an end voltage.

29. The apparatus of claim 28 wherein the time to reach an end voltage is further a function of current draw and temperature.

30. The apparatus of claim 1 wherein the relative test output comprises a predicted time to charge the battery based upon a charge current and a temperature.

31. The apparatus of claim 1 wherein the relative test output comprises a prediction of a largest current at which a load test applied to the battery can be passed.

32. The apparatus of claim 1 wherein the relative test output comprises a prediction of a reserve capacity of a battery.

33. The apparatus of claim 1 wherein the relative test output comprises a prediction of a number of amp hours remaining in the battery.

34. A method for testing a storage battery comprising:
coupling Kelvin connectors to positive and negative terminals of the battery;
measuring a dynamic parameter of the battery using the Kelvin connectors;
receiving an empirical input variable;
determining a relative test output indicative of a condition of the battery based upon the dynamic parameter in the empirical input variable.

35. The method of claim 34 including measuring a voltage across terminals of the battery and the relative test output is further a function of a voltage and is indicative of a time to charge the battery.

36. The method of claim 34 including applying a time varying signal to the battery and wherein the dynamic parameter is measured using a time varying signal.

37. The method of claim 34 wherein the empirical input variable comprises a result of a load test.

38. The method of claim 34 wherein the empirical input variable comprises a result of a bounce back load test.

39. The method of claim 34 wherein the empirical input variable will comprise voltage measurements.

40. The method of claim 34 wherein the empirical input variable comprises state of charge measurements.

41. The method of claim 34 wherein the empirical input variable comprises a visual observation.

42. The method of claim 41 wherein the visual observation is related to corrosion of terminals of the battery.

43. The method of claim 41 wherein the visual observation is related to a cracked battery case.

44. The method of claim 34 wherein the empirical input variable is related to acceptance of charge by the battery from an alternator.

45. The method of claim 34 including charging the battery and the empirical input variable is indicative of charge acceptance by the battery.

46. The method of claim 34 wherein the empirical input variable is related to operator behavior.

47. The method of claim 34 wherein the empirical input variable is indicative of vehicle age.

48. The method of claim 34 wherein the empirical input variable is indicative of vehicle condition.

49. The method of claim 34 wherein the empirical input variable is indicative of a change in a dynamic parameter of the battery.

50. The method of claim 34 wherein the empirical input variable is indicative of charge acceptance of the battery during charging.

51. The method of claim 34 wherein the empirical input variable is indicative of a previous test of the battery.

52. The method of claim 34 wherein the empirical input variable is indicative of battery weight.

53. The method of claim 34 wherein the empirical input variable is indicative of geographic information.

54. The method of claim 34 wherein the empirical input variable is related to time required to charge the battery.

55. The method of claim 34 wherein the empirical input variable is related to a time period during which the battery can power a particular load.

56. The method of claim 34 wherein the empirical input variable is indicative of a vehicle size or engine size that the battery can operate.

57. The method of claim 34 wherein the empirical input variable is related to the number of engine starts performed by the battery per day.

58. The method of claim 34 wherein the relative test output is indicative of a predicted end of life of the battery.

59. The method of claim 34 wherein the relative test output is indicative of a predicted number of engine starts of the vehicle which the battery can perform.

60. The method of claim 34 wherein the relative test output is indicative of a predicted number of charge and discharge cycles which the battery is capable of experiencing.

61. The method of claim 34 wherein the relative test output comprises a prediction of a time to reach an end voltage.

62. The method of claim 61 wherein the time to reach an end voltage is further a function of current draw and temperature.

63. The method of claim 34 wherein the relative test output comprises a predicted time to charge the battery based upon a charge current and a temperature.

64. The method of claim 34 wherein the relative test output comprises a prediction of a largest current at which a load test applied to the battery can be passed.

65. The method of claim 34 wherein the relative test output comprises a prediction of a reserve capacity of a battery.

66. The method of claim 34 wherein the relative test output comprises a prediction of a number of amp hours remaining in the battery.

67. An electronic battery tester implementing the method of claim 34.
